(19) United States
(12) Patent Application Publication
(10) Pub. No.: US 2026/0075996 A1
(43) Pub. Date: Mar. 12, 2026

(54) OPTOELECTRONIC MODULE AND METHOD FOR PRODUCING AN OPTOELECTRONIC MODULE

(71) Applicant: ams-OSRAM International GmbH, Regensburg (DE)

(72) Inventors: Gregory Bellynck, Nittendorf (DE); Simon Jerebic, Donaustauf (DE)

(21) Appl. No.: 19/102,307

(22) PCT Filed: Aug. 11, 2023
(86) PCT No.: PCT/EP2023/072271

§ 371 Date: Feb. 7, 2025

(30) Foreign Application Priority Data
Aug. 16, 2022 (DE) 10 2022 120 594.0

(51) Int. Cl. H10H 20/853; H10H 20/01; H10H 20/854; H10H 20/857

(52) U.S. Cl. CPC H10H 20/853; H10H 20/0362; H10H 20/0364; H10H 20/854; H10H 20/857

(57) ABSTRACT

In an embodiment an optoelectronic module includes a housing body with a main cavity, a dam structure dividing the main cavity into a first subcavity and a second subcavity, a first semiconductor component arranged in the first subcavity and a second semiconductor component arranged in the second subcavity, wherein a boundary surface exists between the dam structure and the housing body.

### CROSS-REFERENCE TO RELATED APPLICATIONS

This patent application is a national phase filing under section 371 of PCT/EP2023/072271, filed Aug. 11, 2023, which claims the priority of German patent application no. 102022120594.0, filed Aug. 16, 2022, each of which is incorporated herein by reference in its entirety.

### TECHNICAL FIELD

An optoelectronic module and a method for producing an optoelectronic module are disclosed. The optoelectronic module is in particular configured to generate or detect electromagnetic radiation, for example light perceptible to the human eye.

### SUMMARY

Embodiments provide an optoelectronic module having a plurality of cavities.

Further embodiments provide a method for producing an optoelectronic module having a plurality of cavities.

According to at least one embodiment, the optoelectronic module comprises a housing body with a main cavity. The housing body is formed, for example, with a material that is suitable for processing in a molding process, in particular with a polysiloxane, an epoxy or a thermoplastic. For example, a polysiloxane is a silicone. The main cavity comprises side surfaces and a bottom surface. The bottom surface is, for example, aligned parallel to a main extension plane of the housing body.

According to at least one embodiment, the optoelectronic module comprises a dam structure. The dam structure is a separate element to the housing body. The housing body and the dam structure are manufactured in separate process steps. The dam structure extends in a lateral direction, preferably from one side surface of the main cavity to an opposite side surface. The lateral direction here and in the following is a direction parallel to a main extension plane of the housing body. Similarly, a vertical direction here and hereinafter is a direction transverse, in particular perpendicular to the main extension plane of the housing body.

The dam structure extends vertically from the bottom surface of the main cavity to at least the connecting line. Furthermore, the dam structure extends in a vertical direction from the bottom surface of the main cavity at most up to an upper edge of the main cavity. In particular, the dam structure extends in a vertical direction up to at least an upper edge of the first and/or second semiconductor component. In other words, a vertical extent of the dam structure is greater than or equal to a vertical extent of the first and/or second semiconductor component. Alternatively, a vertical extent of the dam structure corresponds exactly to a vertical extent of the first and/or second semiconductor component.

The dam structure is formed, for example, with a polysiloxane, an epoxy or a thermoplastic. In particular, the dam structure comprises a wavelength conversion material and is designed to convert electromagnetic radiation of a first wavelength into electromagnetic radiation of a second wavelength. Alternatively, the dam structure is translucent, in particular transparent. In further embodiments, the dam structure is configured to be reflective or absorbing.

According to at least one embodiment of the optoelectronic module, the dam structure divides the main cavity into a first subcavity and a second subcavity. The first and second subcavities are laterally separated by the dam structure. The first and second subcavities are each delimited laterally by the dam structure and the side surfaces of the main cavity.

According to at least one embodiment of the optoelectronic module, a first semiconductor component is arranged in the first subcavity. The first semiconductor component is configured, for example, to control further semiconductor components.

According to at least one embodiment of the optoelectronic module, a second semiconductor component is arranged in the second subcavity. In particular, the second semiconductor component is configured to emit or detect electromagnetic radiation.

According to at least one embodiment of the optoelectronic module, a boundary surface exists between the dam structure and the housing body. The boundary surface is characterized in particular by the fact that a degree of cross-linking, a transmittance, an optical refractive index or a density of the material in the boundary surface differs from the surrounding solid material inside the housing body or the dam structure.

According to at least one embodiment, the optoelectronic module comprises:
a housing body with a main cavity and
a dam structure, whereby
the dam structure divides the main cavity into a first subcavity and a second subcavity,
a first semiconductor component is arranged in the first subcavity,
a second semiconductor component is arranged in the second subcavity and
a boundary surface exists between the dam structure and the housing body.

An optoelectronic module described here is based on the following considerations, among others: Housing bodies that are suitable for a plurality of semiconductor components, so-called multi-die housings, comprise several cavities that are electrically connected to each other. For example, light-emitting diodes and a control element or an additional photodiode are each arranged in different cavities in such housing bodies. The electrical connections between the different components can be made on a second level, for example via conductor tracks or a lead frame, or by stacking several components vertically. These methods may require more space due to a second level and are technically particularly demanding as they require monolithic integrated circuits with several layers or the stacking of different components.

The optoelectronic module described here makes use, among other things, of the idea of initially placing several semiconductor components next to each other in a main cavity of a housing body and, in a further process step, dividing the main cavity into several subcavities by means of a dam structure. Before the dam structure is inserted, the semiconductor components can be electrically conductively connected by means of a connecting line in a wire bonding process. This results in an optoelectronic module with several electrically interconnected semiconductor components, each of which is arranged in its own cavity. Advantageously, light extraction and/or mechanical stability of the optoelectronic module can be improved in this way.

According to at least one embodiment of the optoelectronic module, the dam structure is formed with a material that differs from the material of the housing body. For example, the dam structure is formed with a softer material than the housing body. This advantageously increases design freedom for the optoelectronic module. Another advantage is that the dam structure can be inserted after the semiconductor components have been mounted.

According to at least one embodiment of the optoelectronic module, an angle between the dam structure and the housing body is at most 90°. The angle is measured from outside the dam structure. For example, the dam structure has an undercut. Here and in the following, an undercut refers to a dam structure in which a cross-section increases from the bottom surface of the housing body towards the upper edge of the main cavity. An undercut can have an advantageous visual effect. In addition, an undercut can improve the adhesion of subsequent structures on the dam structure. For example, the dam structure has a convex surface. In particular, the dam structure is in the form of a drop of liquid on a hydrophobic surface. In other words, the dam structure preferably has the shape of a sphere with a flattened side.

According to at least one embodiment of the optoelectronic module, a connecting line electrically conductively connects the first semiconductor component to the second semiconductor component. The connecting line is, for example, a bonding wire. Preferably, the connecting line is formed with a metal or a metal alloy.

According to at least one embodiment of the optoelectronic module, the connecting line extends at least partially through the dam structure. In other words, the connecting line is at least sectionally completely embedded in the dam structure. This enables a particularly compact design of the optoelectronic module. Advantageously, the connecting line is mechanically supported by the dam structure.

According to at least one embodiment of the optoelectronic module, the dam structure comprises a base body and a separating body. In particular, the base body is formed with a material that is different from the separating body. For example, the separating body is radiation permeable and the base body is not radiation permeable. Furthermore, the materials of the base body and the separating body can also be selected with regard to their desired mechanical properties.

According to at least one embodiment of the optoelectronic module, the material of the base body has a higher Young's modulus than the material of the separating body. Advantageously, the separating body is softer and can thus better protect a connecting line, for example, while a harder base body provides the dam structure with sufficient mechanical stability.

According to at least one embodiment of the optoelectronic module, the first semiconductor component comprises an integrated circuit and the second semiconductor component is arranged to emit or detect electromagnetic radiation. A spatial separation between the semiconductor components enables an optimal operating environment for both types of semiconductor components.

According to at least one embodiment of the optoelectronic module, a plurality of second semiconductor components are arranged in the second subcavity. In particular, the semiconductor components are configured to emit electromagnetic radiation of different main wavelengths. The main wavelength is defined here and in the following as a wavelength at which an emission spectrum has a global intensity maximum. Preferably, a second semiconductor component is configured to emit electromagnetic radiation with a main wavelength in the red spectral range. For example, a second semiconductor component is configured to emit electromagnetic radiation with a main wavelength in the green spectral range. Advantageously, a second semiconductor component is configured to emit electromagnetic radiation with a main wavelength in the blue spectral range. Preferably, three semiconductor components are arranged in the second subcavity, which together form an RGB triple that is configured to emit colored mixed radiation.

According to at least one embodiment of the optoelectronic module, the first subcavity is filled with a first filler material. For example, an upper side of the first semiconductor component facing away from the housing body is at least partially covered with the first filler material. Advantageously, the first semiconductor component is completely covered by the first filler material. The first semiconductor component can be particularly well protected from external environmental influences by the first filler material.

According to at least one embodiment of the optoelectronic module, the second subcavity is filled with a second filler material. For example, an upper side of the second semiconductor component facing away from the housing body is at least partially covered with the second filler material. Advantageously, the second semiconductor component is completely covered by the second filler material. The second semiconductor component can be particularly well protected from external environmental influences by the second filler material.

According to at least one embodiment, the first filler material and the second filler material are formed with different materials. Advantageously, the filling materials can be precisely adapted to the application purpose in the respective cavity. For example, the first filler material has a lower optical radiation permeability than the second filler material. In particular, the first filler material has a higher heat conductivity than the second filler material. Thus, unhindered transmission of electromagnetic radiation from and to the second semiconductor component and particularly good cooling of the first semiconductor component can be ensured.

According to at least one embodiment of the optoelectronic module, the first subcavity is filled with material of the dam structure. This enables advantageously simple encapsulation of the first semiconductor component. Thermal stresses between the dam structure and the filled area can thus be reduced or avoided.

According to at least one embodiment of the optoelectronic module, the second subcavity is filled with material of the dam structure. This enables advantageously simple encapsulation of the second semiconductor component. Thermal stresses between the dam structure and the filled area can thus be reduced or avoided.

According to at least one embodiment of the optoelectronic module, the first semiconductor component extends through the dam structure from the first subcavity into the second subcavity. This results in an advantageously simple structure of the optoelectronic module.

According to at least one embodiment of the optoelectronic module, the second semiconductor component is at least partially embedded in the first semiconductor component. Advantageously, this results in particularly simple manufacture, since only the first semiconductor component has to be introduced into the main cavity. Lateral alignment of the first and second semiconductor components in relation to each other is facilitated, as they are already firmly arranged in relation to each other.

According to at least one embodiment of the optoelectronic module, the dam structure is arranged at least sectionally on the first semiconductor component.

In particular, the dam structure extends at least partially over the first semiconductor component. In particular, this means that less material is required for the dam structure.

According to at least one embodiment of the optoelectronic module, the dam structure is arranged in the main cavity of the housing body in such a way that the main cavity is divided into a first subcavity, a second subcavity, a third subcavity and a fourth subcavity. The dam structure has, for example, the shape of a cross when viewed from above on the optoelectronic module. Advantageously, a plurality of different semiconductor components can thus be arranged in their own subcavities.

According to at least one embodiment of the optoelectronic module, the housing body comprises an elevation extending between the first subcavity and the second subcavity.

The elevation is preferably formed with the material of the housing body. In particular, the dam structure is arranged on the elevation. In other words, the elevation forms, for example, a foundation for the dam structure. In particular, there is a boundary surface between the dam structure and the elevation in the housing body. Advantageously, a lateral position of the subsequently applied dam structure can already be defined by the elevation during the manufacture of the housing body. In particular, the elevation delimits a lateral expansion of the dam structure.

A method for producing an optoelectronic module is further disclosed. In particular, the optoelectronic module can be manufactured by means of the method described herein. This means that all features disclosed in connection with the optoelectronic module are also disclosed for the method for producing an optoelectronic module and vice versa.

According to at least one embodiment of the method for producing an optoelectronic module, a housing body with a main cavity is provided. The housing body is preferably produced using a molding process.

According to at least one embodiment of the method for producing an optoelectronic module, a first semiconductor component and a second semiconductor component are arranged in the main cavity. Advantageously, the arrangement of the semiconductor components in the main cavity is simplified before a dam structure is introduced.

According to at least one embodiment of the method for producing an optoelectronic module, a dam structure is introduced into the main cavity in such a way that the main cavity is divided into a first subcavity and a second subcavity. The dam structure is introduced into the main cavity in such a way that the first semiconductor component is arranged in the first subcavity and the second semiconductor component is arranged in the second subcavity. In particular, the dam structure is produced in a separate process step.

According to at least one embodiment of the method for producing an optoelectronic module, the method comprises the following steps:
providing a housing body with a main cavity,
arranging a first semiconductor component and a second semiconductor component in the main cavity,
introducing a dam structure into the main cavity such that the main cavity is divided into a first subcavity and a second subcavity, wherein the first semiconductor component is arranged in the first subcavity and the second semiconductor component is arranged in the second subcavity.

Preferably, the process steps are carried out in the order specified here.

According to at least one embodiment of the method for producing an optoelectronic module, a connecting line is arranged before the dam structure is introduced, which connects the first semiconductor component to the second semiconductor component in an electrically conducting manner. The connecting line is produced in particular by means of wire bonding. Before the dam structure is arranged, the arrangement of the connecting line is advantageously facilitated.

According to at least one embodiment of the method for producing an optoelectronic module, a base body of the dam structure is introduced into the main cavity before a separating body of the dam structure. A multi-part dam structure can be particularly well adapted to a desired application purpose. For example, a radiation-permeable separating body can be placed on a radiation-impermeable base body. In particular, a lateral expansion of the separating body is delimited by a lateral expansion of the base body.

According to at least one embodiment of the method for producing an optoelectronic module, the dam structure is deposited by dispensing. The dam structure is preferably produced using a thixotropic or a particularly viscous material. A thixotropic material advantageously enables particularly easy deposition of the material by dispensing.

According to at least one embodiment of the method for producing an optoelectronic module, the dam structure is manufactured by means of an additive manufacturing process. The use of an additive manufacturing process enables a particularly high degree of design freedom for a shape of the dam structure.

According to at least one embodiment of the method for producing an optoelectronic module, the dam structure is produced by means of a photolithographic process. Photolithographic processes enable a particularly high number of modules to be produced in a parallel process step. Furthermore, the dam structure can be produced with particular precision. A positive photoresist as well as a negative photoresist can be used to produce the dam structure.

An optoelectronic module described here is particularly suitable for use in components with a plurality of highly integrated functions, for example in a vital sign sensor or an intelligent light source.

### BRIEF DESCRIPTION OF THE DRAWINGS

Further advantages and advantageous configurations and further developments of the optoelectronic module result from the following description in connection with the exemplary embodiments shown in the figures.

FIGS. 1A and 1B show schematic sectional views of an optoelectronic module described herein according to a first exemplary embodiment in various steps of a method for its production;

FIG. 2 shows a schematic sectional view of an optoelectronic module described here according to a second exemplary embodiment;

FIG. 3 shows a schematic sectional view of an optoelectronic module described here according to a third exemplary embodiment;

FIG. 4 shows a schematic sectional view of an optoelectronic module described here according to a fourth exemplary embodiment;

FIG. 5 shows a schematic sectional view of an optoelectronic module described here according to a fifth exemplary embodiment;

FIG. 6 shows a schematic sectional view of an optoelectronic module described here according to a sixth exemplary embodiment;

FIGS. 7A and 7B show schematic sectional views of an optoelectronic module described herein according to a seventh exemplary embodiment in various steps of a method for its production;

FIG. 8 shows a schematic top view of an optoelectronic module described here according to the seventh embodiment;

FIG. 9 shows a schematic top view of an optoelectronic module described here according to an eighth exemplary embodiment;

FIG. 10 shows a schematic sectional view of an optoelectronic module described here according to the eighth embodiment;

FIG. 11 shows a schematic sectional view of an optoelectronic module described herein according to a ninth embodiment; and

FIG. 12 shows a schematic sectional view of an optoelectronic module described here according to a tenth exemplary embodiment.

### DETAILED DESCRIPTION OF ILLUSTRATIVE EMBODIMENTS

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

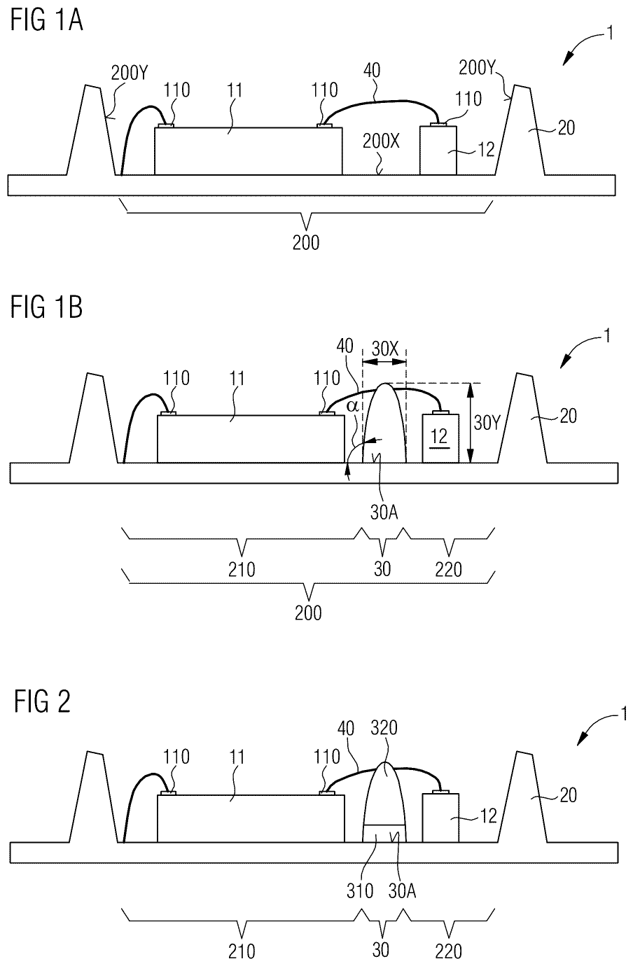

FIGS. 1A and 1B show schematic sectional views of an optoelectronic module 1 described herein according to a first exemplary embodiment in various steps of a method for its production.

FIG. 1A shows a housing body 20 with a main cavity 200. The main cavity comprises a bottom surface 200X and side surfaces 200Y. A first semiconductor component 11 and a second semiconductor component 12 are arranged in the main cavity 200. The first semiconductor component 11 and the second semiconductor component 12 are arranged on the bottom surface 200X of the main cavity 200. The semiconductor components 11, 12 are arranged in a common plane.

The first semiconductor component 11 comprises an integrated circuit and is designed to control a light-emitting diode. The second semiconductor component 12 is configured to emit electromagnetic radiation in the visible spectral range. In particular, the second semiconductor component 12 is a light-emitting diode. The semiconductor components 11, 12 each comprise at least one electrode 110 on a side facing away from the housing body 20.

The first semiconductor component 11 is electrically conductively connected to the second semiconductor component 12 by means of a connecting line 40. The connecting line 40 is a bonding wire. The connecting line 40 extends from an electrode 110 on the first semiconductor component 11 to an electrode 110 on the second semiconductor component 12.

FIG. 1B shows a further step of a method for producing an optoelectronic module 1. A dam structure 30 is arranged between the first semiconductor component 11 and the second semiconductor component 12. The dam structure 30 is arranged in the main cavity 200 of the housing body 20 such that the main cavity 200 is divided into a first subcavity 210 and a second subcavity 220. The dam structure 30 extends in a vertical direction to at least an upper edge of the first and/or second semiconductor component 11, 12. In other words, a vertical extension of the dam structure 30 is greater than or equal to a vertical extension of the first and/or second semiconductor component 11, 12.

The dam structure 30 extends in a vertical direction starting from the bottom surface 200X of the main cavity 200, in particular at least up to the connecting line 40. Furthermore, the dam structure 30 extends in a vertical direction starting from the bottom surface 200X of the main cavity 200 at most up to an upper edge of the main cavity 200. Alternatively, a vertical extension of the dam structure 30 corresponds to a vertical extension of the first and/or second semiconductor component 11, 12.

The vertical extension corresponds to a height 30Y of the dam structure 30 and the lateral extension corresponds to a width 30X of the dam structure 30. For example, the width 30X of the dam structure is between 0.5 mm and 2 mm, in particular the width 30X of the dam structure 30 is 1 mm. For example, the height 30Y of the dam structure is between 0.25 mm and 1 mm, in particular the height 30Y of the dam structure 30 is 0.5 mm. An aspect ratio of the dam structure 30 is preferably 1:2. The aspect ratio here and in the following is a ratio of the height 30Y of the dam structure 30 to the width 30X of the dam structure 30.

A boundary surface 30A is formed between the dam structure 30 and the housing body 20. The boundary surface 30A is characterized in particular by the fact that a degree of cross-linking, a transmittance, an optical refractive index or a density of the material in the boundary surface 30A differs from the surrounding solid material inside the housing body 20 or the dam structure 30.

An angle α between the dam structure 30 and the housing body 20 is at most 90°. In other words, the dam structure 30 forms an angle α of at most 90° with the bottom surface 200X of the main cavity 200. The angle α is measured from outside the dam structure 30 at a point of contact between the dam structure 30 and the housing body 20.

The connecting line 40 runs through the dam structure 30. In other words, the connecting line 40 is embedded in the dam structure 30, at least sectionally. Advantageously, the dam structure 30 thus mechanically stabilizes the connecting line 40.

FIG. 2 shows a schematic sectional view of an optoelectronic module 1 described here according to a second exemplary embodiment. The second exemplary embodiment essentially corresponds to the first exemplary embodiment shown in FIG. 1B. In contrast to the first exemplary embodiment, the dam structure 30 is formed in several separate parts. The dam structure 30 comprises a base body 310 and a separating body 320. The base body 310 is arranged between the bottom surface 200X of the housing body 20 and the separating body 320. A vertical extension of the base body 310 is less than a vertical extension of the separating body 320.

The base body 310 is formed with a material that differs from the material of the separating body 320. For example, the base body 310 is formed with a harder material than the separating body 320. In other words, the Young's modulus of the material of the base body 310 is higher than the Young's modulus of the material of the separating body 320. Advantageously, a desired mechanical support of the connecting line 40 can thus be provided by the softer separating body 320. In a method for producing, for example, the base body 310 is first applied and cured and then the separating body 320 is applied to the base body 310 and cured. Alternatively, the separating body 320 may be applied to the material of the base body 310 before the base body 310 is cured, and a subsequent step of curing the base body 310 and separating body 320 may occur.

Furthermore, the base body 310 and the separating body 320 can have different optical properties. For example, the base body 310 is formed with an opaque material. The separating body 320 may be formed with a radiation permeable material.

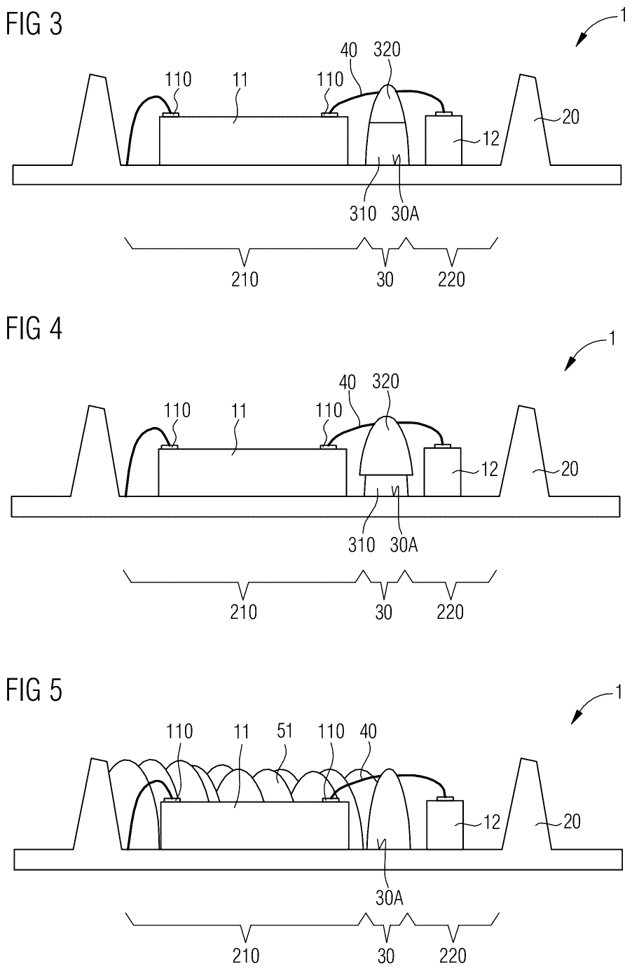

FIG. 3 shows a schematic sectional view of an optoelectronic module 1 described here according to a third exemplary embodiment. The third exemplary embodiment essentially corresponds to the second exemplary embodiment shown in FIG. 2. In contrast to the second exemplary embodiment, a vertical extent of the base body 310 is greater than a vertical extent of the separating body 320.

FIG. 4 shows a schematic sectional view of an optoelectronic module 1 described here according to a fourth exemplary embodiment. The fourth exemplary embodiment essentially corresponds to the second exemplary embodiment shown in FIG. 2. In contrast to the second exemplary embodiment, a lateral extent of the separating body 320 is greater than a lateral extent of the base body 310. In other words, the dam structure 30 has an undercut. The separating body 320 could also have a convex shape, for example in the form of a drop or an inflated balloon.

FIG. 5 shows a schematic sectional view of an optoelectronic module 1 described here according to a fifth exemplary embodiment. Essentially, the fifth exemplary embodiment corresponds to the first exemplary embodiment shown in FIG. 1B. In contrast to the first exemplary embodiment, the first subcavity 210 is at least partially filled with a first filler material 51. The first filler material 51 is in particular the material of the dam structure 30. The first subcavity 210 is in particular completely filled with the first filler material 51. The first filler material 51 can be arranged in the first subcavity 210 in several steps of a method. For example, the dam structure 30 is first introduced into the main cavity 200 and cured. Subsequently, the first subcavity 210 is filled with further material of the dam structure 30. Advantageously, the first semiconductor component 11 is thus particularly well protected from external environmental influences.

Further, the second subcavity 220 may additionally be filled with a second filler material 52. For example, the second subcavity 220 is filled with the material of the dam structure 30. In particular, the first subcavity 210 and the second subcavity 220 are each filled with different materials. Preferably, the second filler material 52 has a higher optical radiation permeability than the first filler material 51. For example, an upper side of the first semiconductor component 11 facing away from the housing body 20 is at least partially covered with the first filler material 51. Advantageously, the first semiconductor component 11 is completely covered by the first filler material 51.

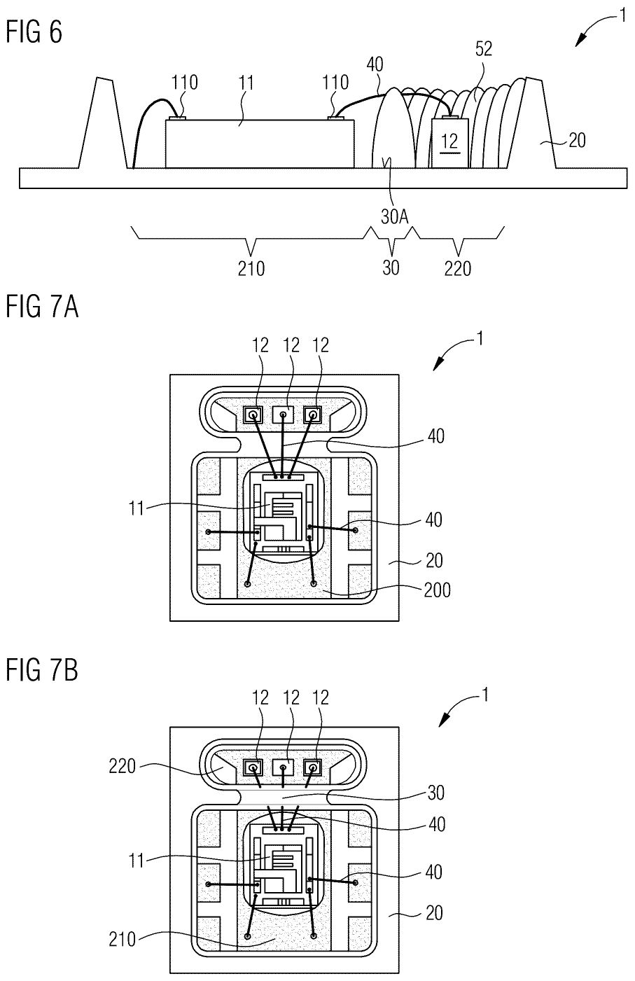

FIG. 6 shows a schematic sectional view of an optoelectronic module 1 described here according to a sixth exemplary embodiment. Essentially, the sixth exemplary embodiment corresponds to the first exemplary embodiment shown in FIG. 1B. In contrast to the first exemplary embodiment, the second subcavity 220 is at least partially filled with a second filler material 52. The second filler material 52 corresponds in particular to the material of the dam structure 30. The second subcavity 220 is preferably completely filled with the second filler material 52. The second filler material 52can be arranged in the second subcavity 220 in several steps of a method. For example, the dam structure 30 is first introduced into the main cavity 200 and cured. Subsequently, the second subcavity 220 is filled with further material of the dam structure 30. Advantageously, the second semiconductor component 12 is thus particularly well protected from external environmental influences.

Further, the first subcavity 210 may additionally be filled with a first filler material 51, as shown in the exemplary embodiment of FIG. 5. Preferably, an upper side of the second semiconductor component 12 facing away from the housing body 20 is at least partially covered with the second filler material 52. Advantageously, the second semiconductor component 12 is completely covered by the second filler material 52.

FIGS. 7A to 7C show schematic sectional views of an optoelectronic module 1 described herein according to a seventh exemplary embodiment in various steps of a method for its production. Essentially, the seventh exemplary embodiment corresponds to the first exemplary embodiment shown in FIG. 1B. In contrast to the first exemplary embodiment, the optoelectronic module 1 comprises a plurality of second semiconductor components 12.

In FIG. 7A, an optoelectronic module 1 is shown according to a first step of a method for its production. The second semiconductor components 12 are each configured to emit electromagnetic radiation with a different main wavelength. A second semiconductor component 12 is configured to emit electromagnetic radiation with a main wavelength in the red spectral range. A second semiconductor component 12 is configured to emit electromagnetic radiation with a main wavelength in the green spectral range. A second semiconductor component 12 is configured to emit electromagnetic radiation with a main wavelength in the blue spectral range. The second semiconductor components 12 together form an RGB triple, which is configured to emit colored mixed radiation.

The first semiconductor component 11 and the second semiconductor components 12 are arranged on a lead frame in a housing body 20. The semiconductor components 11, 12 are electrically conductively connected to each other by means of a plurality of connecting lines 40.

In FIG. 7B, a further step of a method for producing an optoelectronic semiconductor component 1 is shown. In the further step, a dam structure 30 is arranged between the first semiconductor component 11 and the second semiconductor component 12, which divides the main cavity 200 into a first subcavity 210 and a second subcavity 220.

The dam structure 30 is formed with an opaque material. For example, the dam structure 30 comprises a polysiloxane, in particular silicone, with titanium dioxide as filler material. Advantageously, this reduces or prevents optical crosstalk between the first subcavity 210 and the second subcavity 220. The dam structure 30 is formed with a material that has a high optical reflectivity for the electromagnetic radiation emitted in the second semiconductor components 12 during operation. Advantageously, a large proportion of the electromagnetic radiation is thus emitted by the optoelectronic module 1 during operation. In a subsequent process step, the first semiconductor component 11 can be covered with a radiation-impermeable material without the filler material penetrating into the second subcavity 220.

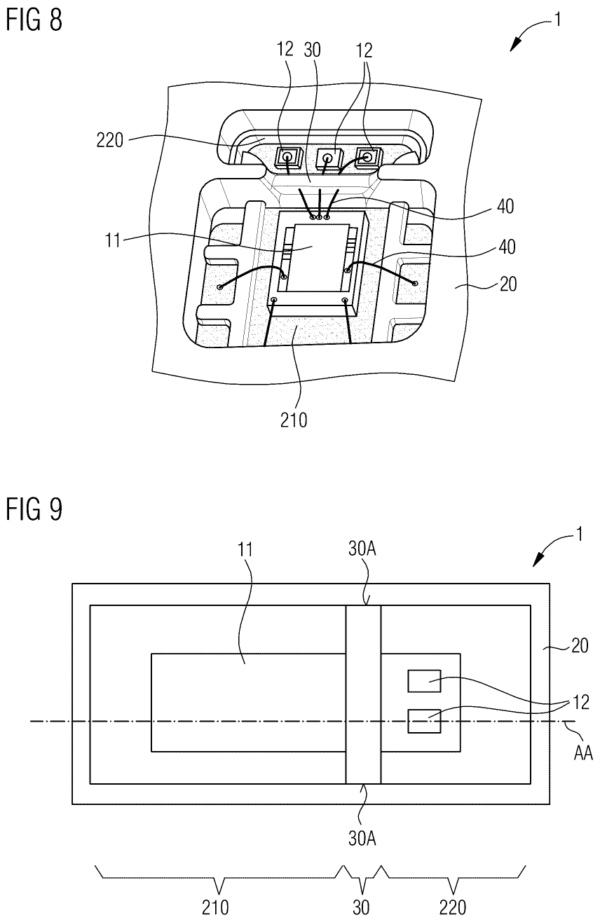

FIG. 8 shows a schematic top view of an optoelectronic module 1 described here according to the seventh exemplary embodiment from a flat angle. It can be clearly seen here that the connecting lines 40 extend transversely through the dam structure 30. In other words, the dam structure 30 completely surrounds the connecting lines 40, at least sectionally. Advantageously, the connecting lines 40 are thus protected from mechanical damage by the dam structure 30.

FIG. 9 shows a schematic top view of an optoelectronic module 1 described herein according to an eighth exemplary embodiment. The optoelectronic module 1 comprises a housing body 20 having a main cavity 200, a first semiconductor component 11 and a plurality of second semiconductor components 12. Further, the optoelectronic module comprises a dam structure 30 dividing the main cavity 200 into a first subcavity 210 and a second subcavity 220. The dam structure 30 extends from a side surface of the main cavity 200 of the housing body 20 to an opposite side surface of the housing body 20. Boundary surfaces 30A are formed between the material of the housing body 20 and the dam structure 30 on the side surfaces of the main cavity 200, respectively.

The first semiconductor component 11 extends completely through the dam structure 30 in the lateral direction. The dam structure 30 is arranged at least sectionally on a side of the first semiconductor component 11 facing away from the housing body 20. The second semiconductor components 12 are at least partially embedded in the first semiconductor component 11. The first semiconductor component 11 extends from the first subcavity 210 into the second subcavity 220.

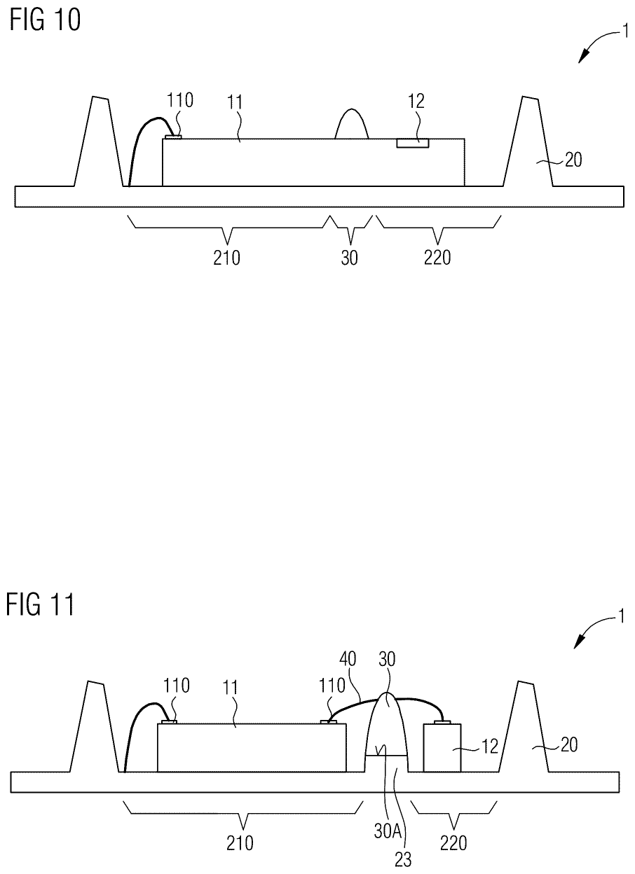

FIG. 10 shows a schematic sectional view of an optoelectronic module 1 described herein according to the eighth exemplary embodiment. The view of FIG. 10 corresponds to a sectional view of an optoelectronic module 1 along the sectional line AA in FIG. 9. In the side view, it is clearly recognizable that the dam structure 30 is partially located on the first semiconductor component 11 and the second semiconductor components 12 are at least partially embedded in the first semiconductor component 11.

Advantageously, this results in a particularly simple assembly of the first and second semiconductor components 11, 12. Furthermore, a connecting line 40 can be dispensed with, since electrical contacting takes place within the first semiconductor component 11.

FIG. 11 shows a schematic sectional view of an optoelectronic module 1 described here according to a ninth exemplary embodiment. The ninth exemplary embodiment essentially corresponds to the second exemplary embodiment shown in FIG. 2. In contrast to the second exemplary embodiment, the housing body 20 comprises an elevation 23 extending between the first subcavity 210 and the second subcavity 220. The elevation 23 is formed with the material of the housing body 20. The dam structure 30 is arranged on the elevations 23. In other words, the elevation 23 forms a foundation for the dam structure 30. A boundary surface 30A exists between the dam structure 30 and the elevation 23 in the housing body 20. Advantageously, the elevations 23 can be used to define a lateral position of the subsequently applied dam structure 30 during the manufacture of the housing body 20. In particular, the elevation 23 delimits a lateral expansion of the dam structure 30.

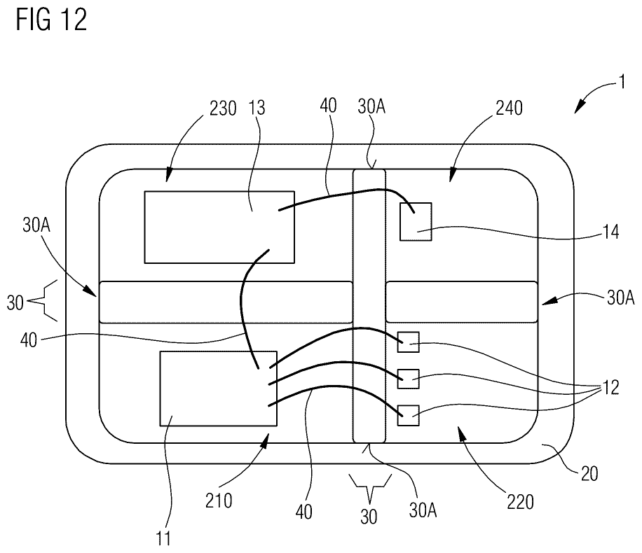

FIG. 12 shows a schematic top view of an optoelectronic module 1 described here according to a tenth exemplary embodiment. The tenth exemplary embodiment essentially corresponds to the first exemplary embodiment shown in FIG. 1B. In contrast to the first exemplary embodiment, the tenth exemplary embodiment comprises a third subcavity 230 and a fourth subcavity 240. Consequently, the dam structure 30 is arranged in the main cavity 200 of the housing body 20 such that the main cavity 200 is divided into a first subcavity 210, a second subcavity 220, a third subcavity 230 and a fourth subcavity 240. The dam structure 30 has the shape of a cross in plan view of the optoelectronic module 1.

A first semiconductor component 1 is arranged in the first subcavity 11. The first semiconductor component 11 comprises an integrated circuit and is provided for controlling a light-emitting diode.

A plurality of second semiconductor components 12 are arranged in the second subcavity 12. The second semiconductor components 12 are configured to emit electromagnetic radiation with a different main wavelength in each case. A second semiconductor component 12 is configured to emit electromagnetic radiation with a main wavelength in the red spectral range. A second semiconductor component 12 is configured to emit electromagnetic radiation with a main wavelength in the green spectral range. A second semiconductor component 12 is configured to emit electromagnetic radiation with a main wavelength in the blue spectral range. The second semiconductor components 12 together form an RGB triple, which is configured to emit colored mixed radiation.

A third semiconductor component 13 is arranged in the third subcavity 230. The third semiconductor component 13 comprises, for example, a memory unit. Preferably, parameters for operating the second semiconductor components 12 are stored in the memory unit.

A fourth semiconductor component 14 is arranged in the fourth subcavity 14. The fourth semiconductor component 14 preferably comprises a sensor. For example, the fourth semiconductor component 14 is a photodiode or a temperature sensor. By means of the measured parameters of the fourth semiconductor component 14, for example, an emission of the second semiconductor components 12 can be monitored.

The first semiconductor component 11 is electrically conductively connected to each of the second semiconductor components 12 in the second subcavity 220 and to the third semiconductor component 13 in the third subcavity 230 by means of a plurality of connecting lines 40. The third semiconductor component 13 is electrically conductively connected to the fourth semiconductor component 14 in the fourth subcavity 240 by means of a connecting line 40.

The invention is not limited by the description based on the embodiments. Rather, the invention includes any new feature as well as any combination of features, which includes in particular any combination of features in the patent claims, even if this feature or combination itself is not explicitly stated in the patent claims or embodiments.

1.-20. (canceled)

21. An optoelectronic module comprising:
a housing body with a main cavity;
a dam structure dividing the main cavity into a first subcavity and a second subcavity;
a first semiconductor component arranged in the first subcavity; and
a second semiconductor component arranged in the second subcavity,
wherein a boundary surface exists between the dam structure and the housing body.

22. The optoelectronic module according to claim 21, wherein the dam structure comprises a material different from a material of the housing body.

23. The optoelectronic module according to claim 21, wherein an angle between the dam structure and the housing body is at most 90°.

24. The optoelectronic module according to claim 21, wherein the dam structure comprises a base body and a separating body.

25. The optoelectronic module according to claim 24, wherein a material of the base body has a higher Young's modulus than a material of the separating body.

26. The optoelectronic module according to claim 21, wherein the first semiconductor component comprises an integrated circuit and the second semiconductor component is configured to emit or detect electromagnetic radiation.

27. The optoelectronic module according to claim 21, wherein a plurality of second semiconductor components are arranged in the second subcavity.

28. The optoelectronic module according to claim 21, wherein the first subcavity is filled a material of the dam structure.

29. The optoelectronic module according to claim 21, wherein the second subcavity is filled with a material of the dam structure.

30. The optoelectronic module according to claim 21, wherein the first semiconductor component extends through the dam structure from the first subcavity into the second subcavity.

31. The optoelectronic module according to claim 21, wherein the second semiconductor component is at least partially embedded in the first semiconductor component.

32. The optoelectronic module according to claim 30, wherein the dam structure is arranged at least sectionally on the first semiconductor component.

33. A method for producing an optoelectronic module, the method comprising:
providing a housing body with a main cavity;
arranging a first semiconductor component and a second semiconductor component in the main cavity; and
introducing a dam structure into the main cavity such that the main cavity is divided into a first subcavity and a second subcavity,
wherein the first semiconductor component is arranged in the first subcavity and the second semiconductor component is arranged in the second subcavity
wherein a connecting line electrically conductively connects the first semiconductor component with the second semiconductor component, and
wherein the connecting line extends at least partially through the dam structure.

34. The method according to claim 33, further comprising, before introducing the dam structure, arranging the connecting line which electrically conductively connects the first semiconductor component to the second semiconductor component.

35. The method according to claim 34, further comprising introducing a base body of the dam structure into the main cavity before a separating body of the dam structure.

36. The method according to claim 33, wherein the dam structure is introduced by dispensing.

37. The method according to claim 33, wherein the dam structure is introduced by an additive manufacturing process.

38. The method according to claim 33, wherein the dam structure is introduced by a photolithographic process.

39. An optoelectronic module comprising:
a housing body with a main cavity;
a dam structure dividing the main cavity into a first subcavity and a second subcavity;
a first semiconductor component arranged in the first subcavity; and
a second semiconductor component arranged in the second subcavity,
wherein a boundary surface exists between the dam structure and the housing body,
wherein a connecting line electrically conductively connects the first semiconductor component with the second semiconductor component, and
wherein the connecting line extends at least partially through the dam structure.
